(19) United States
(12) Patent Application Publication
(10) Pub. No.: US 2025/0183048 A1
(43) Pub. Date: Jun. 5, 2025

(54) ETCHING METHOD AND ETCHING APPARATUS

(71) Applicant: Tokyo Electron Limited, Tokyo (JP)

(72) Inventors: Nobuhiro TAKAHASHI, Nirasaki City (JP); Ayano HAGIWARA, Nirasaki City (JP); Tomoaki FUKUDA, Hillsboro, OR (US); Kento SUZUKI, Nirasaki City (JP); Yusuke IMAI, Nirasaki City (JP)

(21) Appl. No.: 19/047,924

(22) Filed: Feb. 7, 2025

Related U.S. Application Data
(63) Continuation of application No. PCT/JP2024/007682, filed on Mar. 1, 2024.

(30) Foreign Application Priority Data
Mar. 30, 2023 (JP) 2023-056011

(51) Int. Cl. H01L 21/3065; H01L 21/67

(52) U.S. Cl. CPC H01L 21/3065; H01L 21/67069

(57) ABSTRACT

An etching method of etching a silicon germanium film formed on a substrate, includes: supplying a first etching gas, which is a first fluorine-containing gas, to the substrate for a first duration; and after the supplying the first etching gas, supplying a second etching gas, which is a second fluorine-containing gas different from the first etching gas, to the substrate for a second duration shorter than the first duration.

### CROSS-REFERENCE TO RELATED APPLICATION

The application is a Bypass Continuation application of PCT International Application No. PCT/JP2024/007682, filed on Mar. 1, 2024 and designating the United States, the international application being based upon and claiming the benefit of priority from Japanese Patent Application No. 2023-056011, filed on Mar. 30, 2023, the entire content of which is incorporated herein by reference.

### TECHNICAL FIELD

The present disclosure relates to an etching method and an etching apparatus.

### BACKGROUND

When manufacturing a semiconductor device, there are cases where an SiGe film formed on a surface of a semiconductor wafer, which serves as a substrate (hereinafter referred to as “wafer”), is etched. Patent Document 1 discloses that a stacked film, composed of an Si film and an SiGe film, is formed on a wafer and an HF gas and ClF₃ gas are supplied simultaneously when selectively etching the SiGe film of the stacked film.

### PRIOR ART DOCUMENTS

### Patent Documents

Patent Document 1: Japanese Laid-Open Publication No. 2018-170380

### SUMMARY

According to one embodiment of the present disclosure, there is provided an etching method of etching a silicon germanium film formed on a substrate, including: supplying a first etching gas, which is a first fluorine-containing gas, to the substrate for a first duration; and after the supplying the first etching gas, supplying a second etching gas, which is a second fluorine-containing gas different from the first etching gas, to the substrate for a second duration shorter than the first duration.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal front view of a wafer undergoing an etching process according to one embodiment of the present disclosure.

FIG. 2 is a flowchart illustrating the etching process.

FIG. 3 is a chart illustrating a timing of supply/interruption of gases used in the etching process and a timing of pressure changes in a processing container.

FIG. 4 is a longitudinal front view of the wafer after the etching process.

FIG. 5 is a longitudinal side view of an apparatus for performing the etching process according to one embodiment of the present disclosure.

FIG. 6 is a graph illustrating results of an evaluation test.

FIG. 7 is an explanatory diagram illustrating images of substrate chips and various test results obtained in evaluation tests.

FIG. 8 is a graph illustrating results of an evaluation test.

FIG. 9 is a graph illustrating results of an evaluation test.

FIG. 10 is an explanatory diagram illustrating images of substrate chips and various test results obtained in evaluation tests.

FIG. 11 is an explanatory diagram illustrating images of substrate chips and various test results obtained in evaluation tests.

FIG. 12 is a longitudinal side view of a substrate used in evaluation tests.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

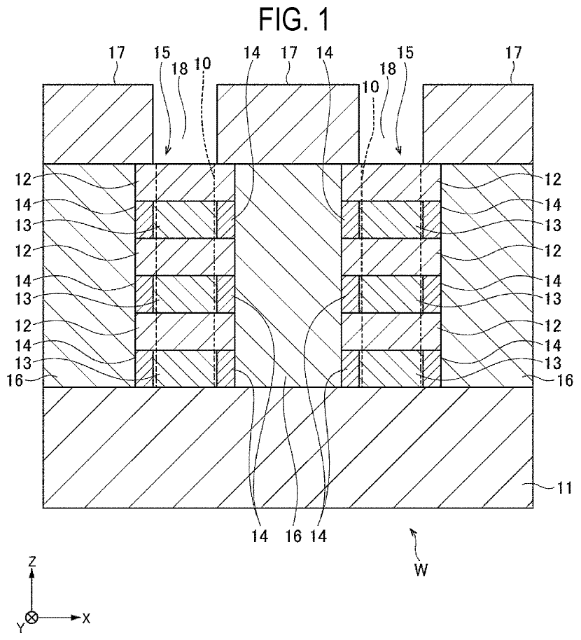

In describing one embodiment of an etching method of the present disclosure, a film structure formed on a wafer W, which is a target substrate to be etched, will be described. FIG. 1 is a longitudinal front view of the film structure. In the drawing, two mutually orthogonal directions in the surface direction of the wafer W are indicated as an X direction and a Y direction, while the direction orthogonal to each of the X direction and the Y direction, corresponding to the thickness direction of the wafer W, is indicated as a Z direction. In the following description, assuming that the wafer W is placed horizontally, the X direction may be referred to as a left-right direction, the Y direction as a front-back direction, and the Z direction as a vertical direction.

Multiple stacks 15, each composed of a silicon (Si) film 12, a silicon germanium (SiGe) film 13, and a porous film 14, are provided on a base film 11 of the wafer W. The SiGe film 13 in the stack 15 is an etching target film. The stacks 15 are provided at intervals in both the front-back direction and the left-right direction and are arranged in a matrix form in a plan view. The porous film 14 is, for example, an insulating film, and more specifically, is a low-k film made of, for example, a carbon-added silicon oxide (SiOC), SiCOH, or SiOCN (i.e., a film composed of Si, oxygen, nitrogen, and carbon).

The structure of the stack 15 will be further described. The porous films 14 are formed adjacent to the left and right of the SiGe film 13, respectively. Thus, a direction in which the SiGe film 13 and the Si film 12 are arranged intersects with a direction in which the SiGe film 13 and the porous film 14 are arranged. If the SiGe film 13 and the porous films 14 adjacent to the left and right of the SiGe film 13 are referred to as adjacent bodies, each stack 15 is configured by stacking a plurality of adjacent bodies and a plurality of Si films 12, and the adjacent body and Si film 12 are alternately positioned in the vertical direction (the Z direction). An upper end portion of the stack 15 is formed by the Si film 12, among the adjacent bodies and Si films 12. Then, a semiconductor film 16 is provided between the stacks 15 arranged side by side. The semiconductor film 16 and the stack 15 are adjacent to each other. The semiconductor film 16 forms a source or drain in a semiconductor product manufactured from the wafer W, and is made of, for example, Si or SiGe.

Further, an upper layer film 17 is provided above the stacks 15 and the semiconductor film 16. The upper layer film 17 has a plurality of grooves 18 extending in the front-back direction, which are spaced apart from each other in the left-right direction. As such, the upper layer film 17 is divided in the left-right direction, and each groove 18 is positioned to overlap with the SiGe film 13 in the vertical direction (the Z direction). Then, a lower portion of the upper layer film 17 extends toward a space between the stacks 15 in the front-back direction, forming an indentation (not illustrated). A recess 10 is defined by the indentation, and the Si film 12 and SiGe film 13 of the stack 15, which form sidewalls. The recess 10 is connected to the groove 18. In other words, the recess 10 opens between the respective upper layer films 17 in the left-right direction (the X direction) and extends in the Z direction. Therefore, the Si film 12 and SiGe film 13, which form the sidewalls of the recess 10, are exposed on the surface of the wafer W, and thus, are exposed to an etching gas supplied above the wafer W. In addition, the semiconductor film 16 is covered with the upper layer film 17 and is not exposed on the surface of the wafer W.

In addition, although a detailed description of the configuration is omitted, the upper layer film 17 is formed of a plurality of types of films such as a silicon oxide (SiO₂) film or an insulating film made of SiOCN. In addition, the upper layer film 17 is resistant to an etching gas to be described later, and prevents the etching of the semiconductor film 16 from above due to the etching gas.

Given the aforementioned film structure, an etching gas supplied above the wafer W may be introduced into the recess 10 through the groove 18, allowing the SiGe film 13 to be etched laterally. More specifically, the gas introduced into the recess 10 flows in the front-back direction (the Y direction) relative to the plane of FIG. 1, thereby etching the SiGe film 13 at each stage. Although the Si film 12 and SiGe film 13 are adjacent to each other, it is required to selectively etch the SiGe film 13, among the Si film 12 and SiGe film 13, and to minimize the roughness (surface roughness) of the Si film 12 after the completion of the etching. Furthermore, it is also required to ensure that no germanium (Ge) residue originating from the SiGe film 13 remains on the surface of the Si film 12 after the completion of the etching.

Further, since the SiGe film 13 is adjacent to the semiconductor film 16 through the porous film 14, the semiconductor film 16 is covered by the upper layer film 17 and porous film 14 even during the etching of the SiGe film 13, which ensures that the semiconductor film 16 is not exposed on the surface of the wafer W. However, during this etching, the etching gas may pass through pores in the porous film 14 and be supplied to the semiconductor film 16. It is also required to etch the SiGe film 13 such that the etching of the semiconductor film 16 is prevented. The etching in the present embodiment may meet these requirements.

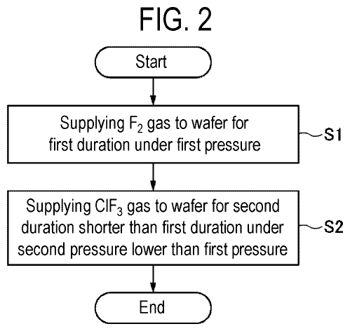

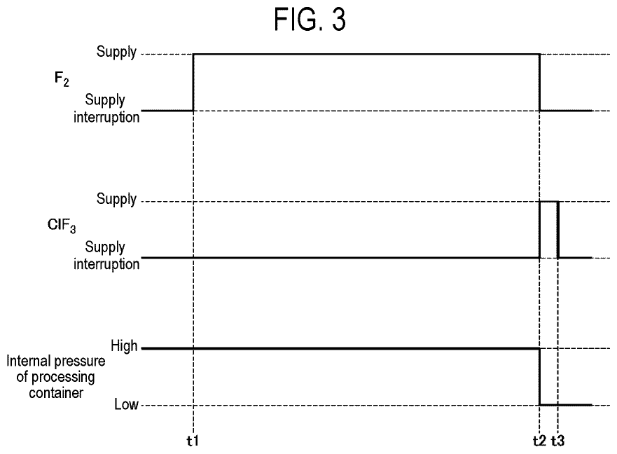

Hereinafter, the etching process of the present embodiment will be specifically described with reference to the flowchart in FIG. 2 and the timing chart in FIG. 3. The etching process is performed by supplying two types of fluorine-containing etching gases to the wafer W described in FIG. 1 while the wafer W is stored in a processing container in which a vacuum atmosphere is created. The timing chart illustrates the timing of the supply/interruption of each etching gas in the processing container and the timing of pressure changes in the processing container.

First, the wafer W described in FIG. 1 is loaded into the processing container. Then, by evacuating the processing container, a vacuum atmosphere at a predetermined first pressure is created in the processing container. Then, a first etching gas, for example, a fluorine (F₂) gas, is supplied into the processing container (time t1, step S1). This selectively etches the SiGe film 13, among the Si film 12 and SiGe film 13. Once a preset first duration has elapsed from time t1 and time t2 is reached, the supply of F₂ gas into the processing container is interrupted, and at the same time, a supply of a second etching gas, for example, a chlorine trifluoride (ClF₃) gas, into the processing container is initiated. Furthermore, the internal pressure of the processing container is lowered to a second pressure lower than the first pressure by adjusting an exhaust flow rate in the processing container (step S2). The supplied ClF₃ gas purges the F₂ gas remaining in the processing container from the processing container, and etches a residue of the SiGe film 13.

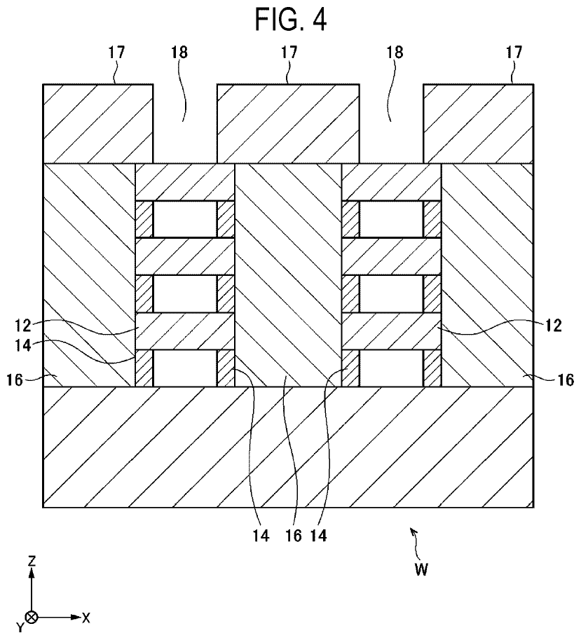

Once a preset second duration from time t2 has elapsed, and time t3 is reached, the supply of ClF₃ gas into the processing container is interrupted. The second duration (from time t2 to time t3) is shorter than the first duration (from time t1 to time t2). FIG. 4 illustrates a longitudinal front view of the wafer W after the completion of the etching process. An inert gas is supplied into the processing container to purge the ClF₃ gas from the processing container, making the completion of the etching process. The wafer W is then unloaded from the processing container.

In the etching process of the present embodiment, two-stage etching is performed by changing the type of gas. To explain the rationale, when etching the SiGe film of the structure in which the Si film and SiGe film are adjacent to each other, using ClF₃ gas may reduce the adhesion of Ge residues to the Si film and the roughness of the Si film after etching, compared to when using F₂ gas, as demonstrated in the evaluation tests to be described later. However, ClF₃ gas has high etching capability for the Si film, the Si film is easily etched. In other words, using only ClF₃ gas makes it difficult to selectively etch the SiGe film.

Therefore, first, F₂ gas is supplied to the wafer W in FIG. 1 for a relatively long duration. As demonstrated in the evaluation tests to be described later, it is difficult to etch the Si film 12 with F₂ gas. In other words, F₂ gas is capable of etching the SiGe film 13 with high selectivity relative to the Si film 12.

Then, after the SiGe film 13 has been largely removed with F₂ gas, ClF₃ gas is supplied for a relatively short duration. This makes it possible to reduce the roughness of the Si film 12 and the adhesion of Ge residues to the Si film 12 while preventing the etching of the Si film 12.

ClF₃ gas exhibits relatively high etching capability for the Si film as described above, but also exhibits relatively high etching capability for the SiGe film, as demonstrated in the evaluation tests to be described later. Therefore, the semiconductor film 16 formed on the wafer W has high susceptibility to etching by ClF₃ gas even though it is made of either Si or SiGe as described above. However, since ClF₃ gas is supplied for a relatively short duration in the present embodiment, ClF₃ gas is prevented from passing through pores in the porous film 14 and being supplied to the semiconductor film 16. Therefore, etching of the semiconductor film 16 may also be prevented.

Further, by evacuating the processing container, the second pressure during the ClF₃ gas supply duration from time t2 to time t3 is lower than the first pressure during the F₂ gas supply duration from time t1 to time t2. In the supply of the ClF₃ gas, such a relatively low internal pressure of the processing container prevents ClF₃ gas from remaining in the processing container for a long duration. This more reliably prevents the etching of the Si film 12 and the semiconductor film 16. In contrast, in the supply of the F₂ gas, a relatively high internal pressure of the processing container allows F₂ gas to remain in the processing container for a relatively long duration and act effectively on the SiGe film 13. Therefore, a reduction in the etching rate is prevented.

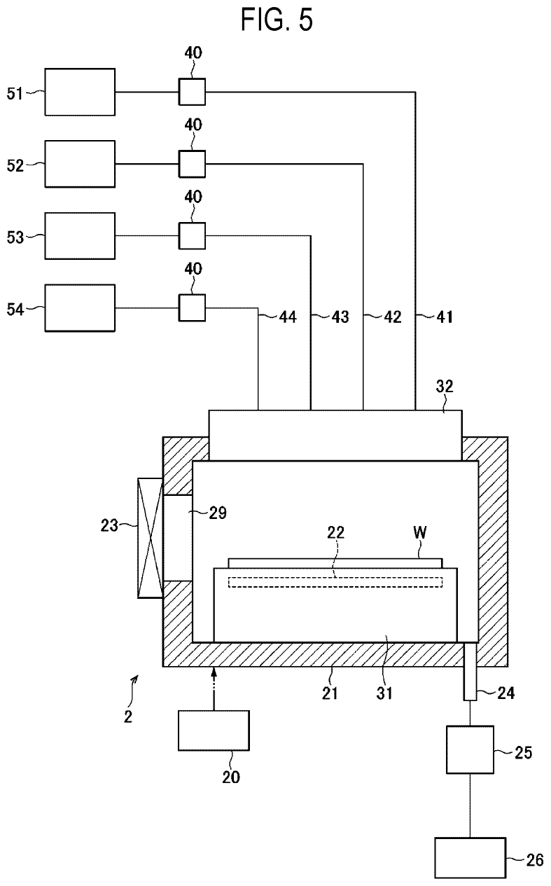

Next, an etching apparatus 2, which is an example of an etching apparatus capable of performing the etching process described with reference to FIGS. 2 and 3, will be described. FIG. 5 is a longitudinal side view of the etching apparatus 2. In the drawing, reference numeral 21 denotes the aforementioned processing container, which constitutes the etching apparatus 2. In the drawing, reference numeral 29 denotes a transfer port for the wafer W that opens on a sidewall of the processing container 21, and is opened or closed by a gate valve 23. A stage 31 on which the wafer W is placed is installed inside the processing container 21. The stage 31 is provided with a lift pin (not illustrated). A delivery of the wafer W between the stage 31 and a substrate transfer mechanism arranged outside the processing container 21 is performed via the lift pin.

A temperature adjuster 22 is embedded in the stage 31 and is used to adjust a temperature of the wafer W placed on the stage 31. The temperature adjuster 22 is configured, for example, as a flow path that forms a part of a circulation path through which a temperature adjustment fluid such as water flows, and the temperature of the wafer W is adjusted by heat exchange with the fluid. However, the temperature adjuster 22 is not limited to such a fluid flow path, and may also be configured by, for example, a heater for performing resistance heating.

Further, one end of an exhaust pipe 24 opens into the processing container 21, while the other end of the exhaust pipe 24 is connected to an exhaust mechanism 26, which is constituted by a vacuum pump, via a valve 25, which is a pressure change mechanism. By adjusting an opening degree of the valve 25, the exhaust flow rate within the processing container 21 is adjusted to achieve a desired vacuum pressure inside the processing container 21. In other words, as described above, switching between the first pressure and the second pressure may be achieved by changing the opening degree of the valve 25.

A shower plate 32 is installed in an upper portion of the processing container 21 to face the stage 31. The shower plate 32 is connected to downstreams of gas supply paths 41 to 44, while the upstreams of the gas supply paths 41 to 44 are connected to gas sources 51 to 54, respectively, via respective flow rate adjusters 40. Each flow rate adjuster 40 includes a valve and a mass flow controller. The supply and interruption of respective gases from the gas sources 51 to 54 to the downstreams are performed by the opening and closing of the valves included in the flow rate adjusters 40. Further, the flow rates of the respective gases supplied to the downstream are adjusted by the respective flow rate adjusters 40. These gases supplied to a gas flow path provided in the shower plate 32 are discharged downward from multiple outlets formed on a lower surface of the shower plate 32.

The gas sources 51, 52, 53 and 54 supply F₂ gas, ClF₃ gas, N₂ gas, and Ar gas, respectively, and the gases are supplied into the processing container 21 through the shower plate 32, respectively. The gases may be supplied independently of each other by the respective flow rate adjusters 40. During the etching process, N₂ gas, which is an inert gas, is supplied as a carrier gas into the processing container 21 via the shower plate 32, together with an etching gas (F₂ gas and ClF₃ gas). Further, after the etching gas supply is completed, N₂ gas continues to be supplied into the processing container and acts as a purge gas to purge an interior of the processing container. Further, Ar gas, which is also an inert gas, is used for adjusting a partial pressure of the etching gas, and is supplied into the processing container, together with the etching gas. The gas supply path 41 through which F₂ gas flows, the flow rate adjuster 40 installed in the gas supply path 41, and the shower plate 32 constitute a first gas supplier. The gas supply path 42 through which ClF₃ gas flows, the flow rate adjuster 40 installed in the gas supply path 42, and the shower plate 32 constitute a second gas supplier.

Further, the etching apparatus 2 includes a controller 20, which is a computer. The controller 20 includes a program, a memory, and a CPU. The program incorporates instructions (each step) that enable the above-described processing and a transfer of the wafer W. This program is stored in a non-transitory storage medium such as a compact disk, a hard disk, a magneto-optical disk, or a DVD, and is installed to the controller 20. The controller 20 outputs a control signal to each component of the etching apparatus 2 using the program to control the operation of each component. Specifically, examples of the operation of the etching apparatus 2 that is controlled in this manner include an adjustment of a temperature of a fluid supplied to the stage 31 (i.e., the processing temperature of the wafer W), the supply and interruption of each gas from the shower plate 32, and the adjustment of the exhaust flow rate by the valve 25 (i.e., the adjustment of the internal pressure of the processing container 21).

The opening degree of the valve 25 in the etching apparatus 2 is adjusted so that the first pressure from time t1 to time t2 is set to, for example, a range of 1.33 Pa (10 mTorr) to 133 Pa (1000 mTorr), and the second pressure from time t2 to time t3 is set to, for example, a range of 0 Pa to 133 Pa. Further, the temperature of the wafer W from time t1 to time t3 is set to, for example, a range of −50 degrees C. to 150 degrees C. by the temperature adjuster 22. Further, the flow rates of the respective gases supplied into the processing container fall within a range of 1 to 500 sccm for F₂ gas, 0.1 to 10 sccm for ClF₃ gas, 50 to 1000 sccm for N₂ gas, and 10 to 1000 sccm for Ar gas, respectively.

Further, as described above, the inert gas (N₂ gas or Ar gas) is supplied into the processing container, together with F₂ gas and ClF₃ gas. Regarding a flow rate relationship between F₂ gas, ClF₃, and the inert gas supplied into the processing container, for example, the flow rate ratio of F₂ gas to the inert gas is greater than the flow rate ratio of ClF₃ gas to the inert gas. In other words, when supplying F₂ gas and ClF₃ gas to the wafer W, respectively, ClF₃ gas may be supplied at a higher dilution ratio using the inert gas, compared to F₂ gas. By adjusting the flow rates of these gases in this manner, it is possible to more reliably prevent ClF₃ gas from etching the Si film 12 and the semiconductor film 16.

It has been described that F₂ gas is used as the first etching gas, but other fluorine-containing gases capable of selectively etching the SiGe film 13 relative to the Si film 12 may also be used. For example, a mixed gas of HF gas and F₂ gas may be used instead of F₂ gas. Further, a fluorine-containing gas having a relatively stronger etching effect on the SiGe film 13 may be used as the second etching gas instead of ClF₃ gas. For example, an iodine heptafluoride (IF₇) gas or nitrogen trifluoride (NF₃) gas may be used as the second etching gas. In addition, the term “containing fluorine” here refers to including fluorine as a constituent component, not as an impurity.

In the processing example illustrated in the chart of FIG. 3, ClF₃ gas is supplied simultaneously with the supply interruption of F₂ gas, such that and the purge of F₂ gas from the processing container 21 is performed using ClF₃ gas. However, there may be an interval between a timing at which the supply of F₂ gas is interrupted and a timing at which the supply of ClF₃ gas is initiated. Then, during this interval, F₂ gas may be purged from the processing container using the inert gas such as N₂ gas. However, in order to shorten the processing duration, it is desirable to supply ClF₃ gas simultaneously with the supply interruption of F₂ gas to purge F₂ gas using ClF₃ gas, as illustrated in FIG. 3.

The etching method described in the present embodiment is particularly effective for a substrate in which the SiGe film 13 and the Si film 12 are adjacent to each other, since the etching method has the effect of reducing the roughness of the Si film 12 adjacent to the SiGe film 13 as described above. However, the etching method may also be applied to etch the SiGe film 13 that is not adjacent to the Si film 12 since it also enables a reduction in the amount of Ge residues originating from the SiGe film 13 after etching.

The embodiments disclosed herein should be considered as illustrative and not restrictive in all respects. The above embodiments may be omitted, replaced, modified and combined in various ways without departing from the scope and spirit of the appended claims.

### [Evaluation Test 1]

Each evaluation test performed in relation to the technique of the present disclosure will be described. In Evaluation Test 1, a plurality of wafers W, each having two chips fixed to a surface thereof, was prepared. Then, the etching apparatus 2 described in the embodiment was used to perform etching by changing the type of etching gas and the etching duration for each wafer W. One of the two chips is composed of an SiGe film serving as an upper layer film stacked on an Si film serving as a lower layer film. The thickness of the SiGe film was 50 nm, with a Ge content in the film being 25%. The other chip is a polysilicon film. After the etching the chip where the SiGe film has been formed, the amount of Ge was measured using X-ray photoelectron spectroscopy (XPS), a root mean square roughness (RMS) was measured using atomic force microscope (AFM), images were acquired using scanning electron microscope (SEM), and an etching amount of the SiGe film was measured. An etching amount was also measured for the polysilicon film chip.

The etching was performed by supplying, as an etching gas, F₂ gas, ClF₃ gas, and a combination of F₂ gas and ClF₃ gas to the wafer W, respectively. Tests using F₂ gas, ClF₃ gas, the combination of F₂ gas and ClF₃ gas were designated as Evaluation Tests 1-1, 1-2 and 1-3, respectively. In Evaluation Test 1-3, the supply initiation timing and the supply completion timing for F₂ gas and ClF₃ gas were aligned to supply both the gases simultaneously. In each of Evaluation Tests 1-1 to 1-3, the etching was performed by changing the etching gas supply duration (etching duration) for each wafer W. In addition, when performing the etching, the temperature of the wafer W, the internal pressure of the processing container 21, and the flow rate of each gas supplied into the processing container were set to values within the ranges specified in the embodiment.

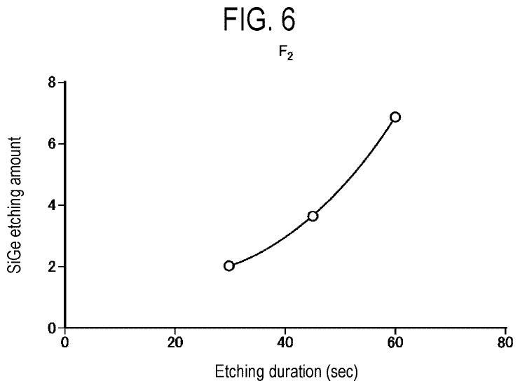

In describing the test results, the etching duration, which was set such that the etching amount of the SiGe film of the chip is equal to 50 nm of the film thickness of the SiGe film (meaning that the SiGe film was completely removed), may be referred to as the “Just Etching (JE)” duration. A duration, for which etching continues beyond the etching duration to excessively etch the 50 nm SiGe film, may be referred to as the “Over Etching (OE)” duration. Specifically, assuming that the thickness of the SiGe film of the chip is 100 nm, 150 nm, 300 nm, or 550 nm, the duration for which the etching amount of the SiGe film is equal to the thickness of the SiGe film is expressed as the duration for performing OE of 100%, 200%, 500%, or 1000%. In addition, the duration for performing each OE was calculated based on a relationship between the etching amount of the SiGe film with a thickness of 50 nm or less and the etching duration corresponding to this etching amount (see the graph in FIG. 6).

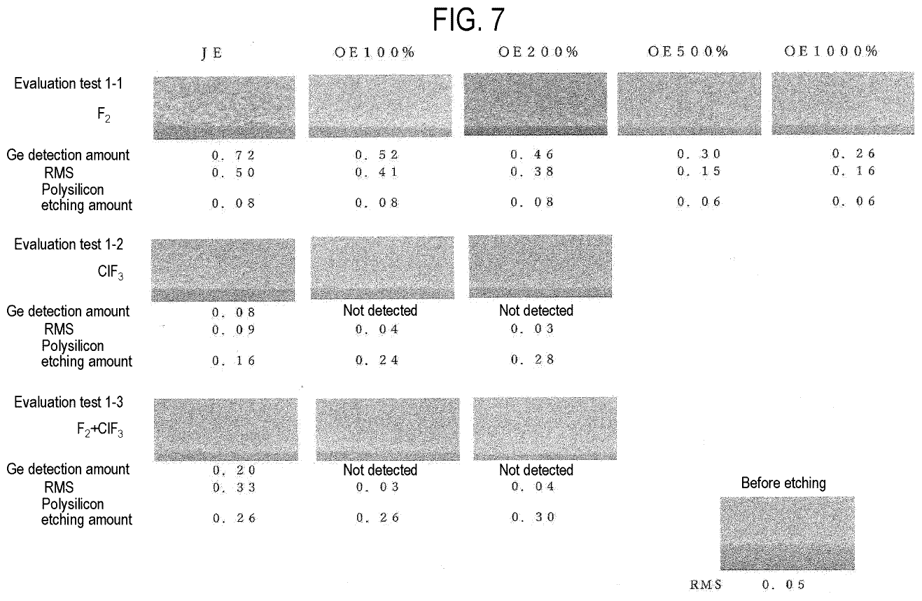

FIG. 7 illustrates SEM images, Ge detection amounts, RMS values, and polysilicon film etching amounts acquired by the processing of JE and each OE for Evaluation Tests 1-1 to 1-3. As mentioned above, the SEM images, the Ge detection amounts, and the RMS values were acquired from the chip where the SiGe film has been formed (i.e., the chip having a surface made of Si by removing the SiGe film). In addition, the Ge detection amounts were actually acquired as percentage values and the RMS values and polysilicon film etching amounts were actually acquired in nanometers, but the respective values illustrated in the table were normalized by dividing the acquired values by a predetermined coefficient. For the Ge detection amounts, higher values in the drawing indicate the greater amount of residues on the Si film. For the RMS values, higher values in the drawing indicate greater roughness. For the polysilicon film etching amounts, higher values in the drawing indicate greater etching amounts. In addition, for comparison, FIG. 7 also illustrates images and normalized RMS values for the surface of the chip where the SiGe film was formed before etching in the right lower end of the drawing.

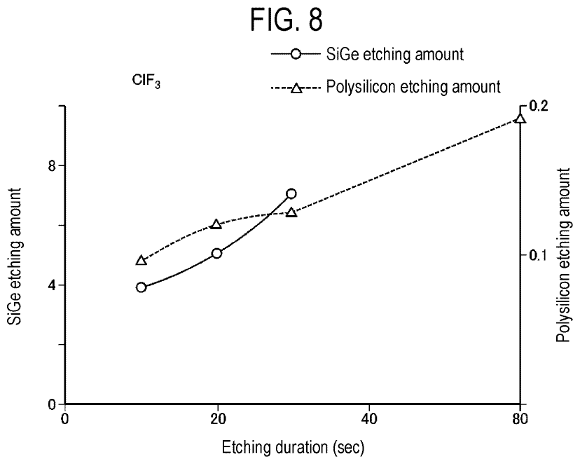

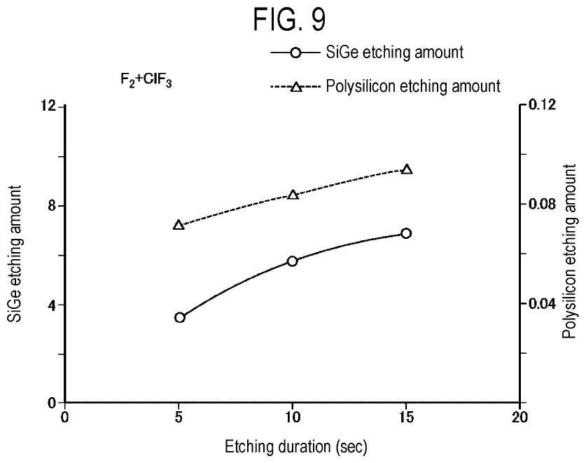

FIG. 8 is a graph illustrating a relationship between the etching duration, the SiGe film etching amount, and the polysilicon film etching amount by etching with ClF₃ gas, which was the basis for Evaluation Test 1-2. Further, FIG. 9 is a graph illustrating a relationship between the etching duration, the SiGe film etching amount, and the polysilicon film etching amount by etching with the combination of F₂ gas and ClF₃ gas, which was the basis for Evaluation Test 1-3. As with Evaluation Test 1-1, Evaluation Tests 1-2 and 1-3 were performed by determining the JE and OE durations from the correspondence between the SiGe film etching amount and the etching duration. The vertical axes of each graph represent the etching amounts of the respective films, obtained by dividing the acquired values by a predetermined coefficient. In addition, the predetermined coefficient is the same as the coefficient used in FIG. 6 to normalize the polysilicon film etching amount.

The results of Evaluation Test 1-1 using F₂ gas will be described. In Evaluation Test 1-1 illustrated in FIG. 7, JE, OE 100%, OE 200%, OE 500%, and OE 1000% correspond to specific etching durations of 82 seconds, 145 seconds, 208 seconds, 397 seconds, and 712 seconds, respectively. As illustrated in FIG. 6, the SiGe film etching amount increases as the etching duration with F₂ gas increases. On the other hand, as illustrated in FIG. 7, the polysilicon film etching amounts for JE and all OE etching durations remain approximately constant and are relatively low. Therefore, as described in the embodiment, it can be seen that etching the Si film and SiGe film using F₂ gas enables highly selective etching of the SiGe film.

However, the Ge detection amounts are relatively high. It was confirmed that the Ge detection amounts decrease as the OE percentage increases, but Ge residues were still detected even at OE 1000%. Further, it was confirmed that the RMS values decrease as the OE percentage increases, but for lower OE percentages and JE, relatively high RMS values (i.e., relatively greater roughness) were observed.

Next, the results of Evaluation Test 1-2 using ClF₃ gas will be described. In Evaluation Test 1-2 illustrated in FIG. 7, JE, OE 100%, and OE 200% correspond to specific etching durations of 50 seconds, 115 seconds, and 179 seconds, respectively. For the Ge detection amounts, a relatively low value was observed at JE, and no Ge residues were detected at OE 100% and OE 200%. The RMS values at JE, OE 100%, and OE 200% were comparable to the RMS value before etching, and were lower than the RMS values observed in Evaluation Test 1-1 at JE, OE 100%, and OE 200%. Then, the RMS values at OE 100% and OE 200% were particularly low.

However, as illustrated in FIG. 8, when ClF₃ gas is used, as the etching duration increases, not only the SiGe film etching amount but also the polysilicon film etching amount increase. Then, the respective polysilicon film etching amounts at JE, OE 100%, and OE 200% in Evaluation Test 1-2 were found to be greater than the respective polysilicon film etching amounts at JE and each OE in Evaluation Test 1-1.

Next, the results of Evaluation Test 1-3 using F₂ gas+ClF₃ gas will be described. In Evaluation Test 1-3 illustrated in FIG. 7, JE, OE 100%, and OE 200% correspond to specific etching durations of 24 seconds, 54 seconds, and 85 seconds, respectively. As with Evaluation Test 1-2, for the Ge detection amounts, a relatively low value was observed at JE, and no Ge residues were detected at OE 100% and OE 200%. Further, the RMS values at OE 100% and OE 200% were particularly low and comparable to the RMS value before etching.

However, as illustrated in FIG. 9, even when F₂ gas+ClF₃ gas was used, as the etching duration increases, not only the SiGe film etching amount but also the polysilicon film etching amount increase. Then, the respective polysilicon film etching amounts at JE, OE 100%, and OE 200% in Evaluation Test 1-3 were found to be greater than the respective polysilicon film etching amounts at JE and each OE in Evaluation Test 1-1.

As described above, it was confirmed from the results of Evaluation Test 1 that the use of ClF₃ gas as an etching gas may reduce the amount of Ge residues on the Si film after etching and may reduce the roughness of the Si film. However, it was also found that the Si film etching amount becomes relatively higher compared to the use of F₂ gas.

### [Evaluation Test 2]

In Evaluation Test 2, etching was performed on the wafer W having the same configuration as in Evaluation Test 1 under the same condition as that at OE 100% in Evaluation Test 1-1. That is, the etching was performed using F₂ gas. Then, following this etching using F₂ gas, F₂ gas and NH₃ gas were supplied into the processing container to perform both the purge of F₂ gas and etching in the processing container. In addition, an internal pressure of the processing container during a duration for which F₂ gas was supplied alone (duration for which purge was performed) was set to be lower than an internal pressure of the processing container during a duration for which both F₂ gas and NH₃ gas were supplied. After such etching, as with Evaluation Test 1, SEM images, Ge detection amounts, and RMS values were acquired from the chip where the SiGe film has been formed, and the etching amount was also acquired from the polysilicon film chip. The supply duration of F₂ gas and NH₃ gas (duration for which purge was performed) was changed for each wafer W, and tests performed by setting this supply duration to 5 seconds, 10 seconds, and 20 seconds were designated as Evaluation Tests 2-1, 2-2, and 2-3, respectively.

### [Evaluation Test 3]

Evaluation Test 3 was performed under the same processing condition as in Evaluation Test 2, except that there was no duration for which F₂ gas was supplied alone, among F₂ gas and NH₃ gas. Accordingly, in Evaluation Test 3, etching was performed only during a duration for which both F₂ gas and NH₃ gas were supplied simultaneously to the wafer W (duration corresponding to the purge in Evaluation Test 2). Tests performed by setting the supply duration of F₂ gas and NH₃ gas to 5 seconds, 10 seconds, and 20 seconds as in Evaluation Test 2 were designated as Evaluation Tests 3-1, 3-2, and 3-3, respectively. In Evaluation Test 3, the respective SiGe film and polysilicon film etching amounts were measured.

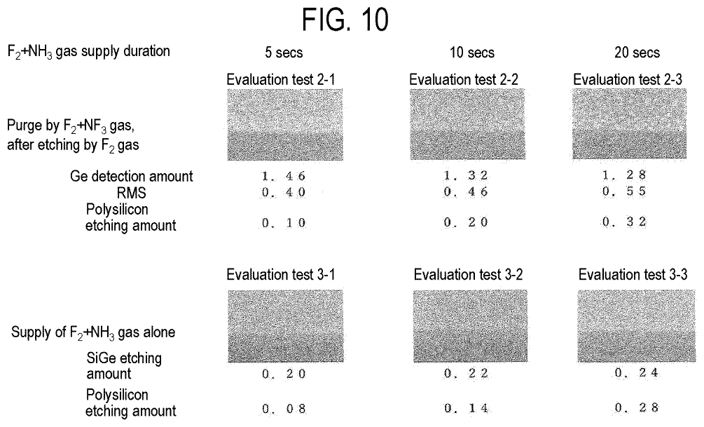

The results of Evaluation Tests 2 and 3 are illustrated in FIG. 10. The values in the table were normalized in the same manner as in Evaluation Test 1. Based on the results of Evaluation Test 2, the Ge detection amounts and RMS values were relatively high across Evaluation Tests 2-1 to 2-3. Further, among Evaluation Tests 2-1 to 2-3, the longer the supply duration of F₂ gas and NH₃ gas, the greater the polysilicon film etching amount. Based on the results of Evaluation Test 3, there was no significant difference in the SiGe film etching amount among Evaluation Tests 3-1 to 3-3, but the polysilicon film etching amount increase as the etching duration increase. Accordingly, it can be seen from the results of Evaluation Tests 2 and 3 that the action of F₂ gas and NH₃ gas results in the relatively significant etching of the polysilicon film.

### [Evaluation Test 4]

In Evaluation Test 4, processing was performed under the same condition as in Evaluation Test 2, except that ClF₃ gas was supplied for purge instead of purge with F₂ gas and NH₃ gas in Evaluation Test 2, and a range of the purge duration was different from the range of 5 to 20 seconds set in Evaluation Test 2. Accordingly, in Evaluation Test 4, ClF₃ gas was supplied after F₂ gas was supplied, as in the embodiment. The internal pressure of the processing container during the duration for which ClF₃ gas is supplied was also set to be lower than the internal pressure of the processing container during the duration for which F₂ gas was supplied, as in the embodiment. Tests performed by setting the ClF₃ gas supply duration to 5 seconds, 20 seconds, and 60 seconds were designated as Evaluation Tests 4-1, 4-2, and 4-3, respectively.

### [Evaluation Test 5]

Evaluation Test 5 was performed under the same processing condition as in Evaluation Test 4, except that the duration for which etching was performed by supplying F₂ gas was not provided. Therefore, in Evaluation Test 5, etching was performed using only ClF₃ gas. Tests performed by setting the ClF₃ gas supply duration to 5 seconds, 20 seconds, and 60 seconds as in Evaluation Test 4 were designated as Evaluation Tests 5-1, 5-2, and 5-3, respectively. As with Evaluation Test 3, the respective SiGe film and polysilicon film etching amounts were measured in Evaluation Test 5.

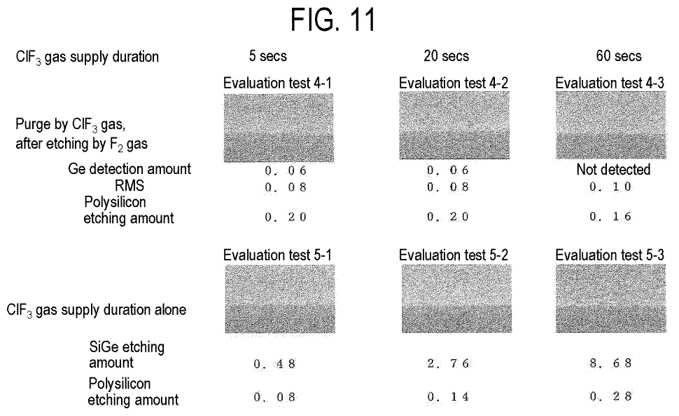

The results of Evaluation Tests 4 and 5 are illustrated in FIG. 11. The values in the table were normalized in the same manner as in Evaluation Test 1. Based on the results of Evaluation Test 4, the Ge detection amounts were kept low, respectively, in Evaluation Tests 4-1 to 4-3, which were lower than the Ge detection amounts observed in Evaluation Tests 2-1 to 2-3. Further, the RMS values were also kept low, respectively, in Evaluation Tests 4-1 to 4-3, which were lower than the RMS values observed in Evaluation Tests 2-1 to 2-3. Further, the respective polysilicon film etching amounts in Evaluation Tests 4-1 to 4-3 were relatively low and comparable to the values observed in Evaluation Tests 2-1 to 2-3.

It can be seen from the results of Evaluation Test 4 that in processing the wafer W having the film structure illustrated in FIG. 1 using the method described in the embodiment, among the Si film 12 and the SiGe film 13, the SiGe film 13 may be selectively etched, preventing the formation of Ge residues. Further, it can be seen that the roughness of the Si film 12 after etching may be reduced.

In addition, as with Evaluation Test 1, the results of Evaluation test 5 indicate that, as the ClF₃ gas supply duration increases, the SiGe film etching amount and the polysilicon film etching amounts increase. The polysilicon film etching amount was relatively high in Evaluation Test 5-2, but was relatively low in Evaluation Test 5-1. It is considered from these results that the ClF₃ gas supply duration from time t2 to time t3 (the second duration) illustrated in FIG. 3 is preferably shorter than 20 seconds, and more preferably 5 seconds or less.

### [Evaluation Test 6]

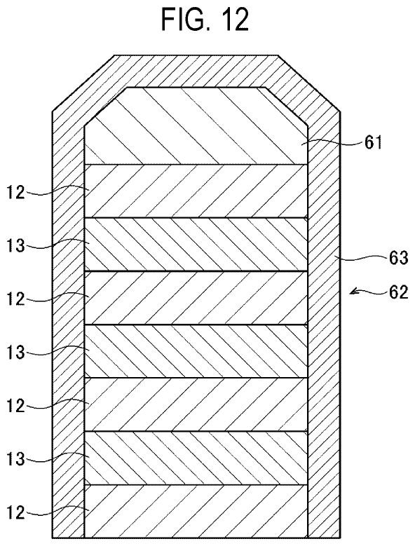

For Evaluation Test 6-1, a substrate having a film structure illustrated in FIG. 12 was prepared. The film structure includes a stack 62 in which the Si film 12 and the SiGe film 13 are alternately stacked upward, and a silicon nitride (SiN) film 61 is formed on an uppermost Si film 12. Then, a porous film 63, which is a low-k film, is formed to cover from an upper portion to a lateral portion of the stack 62. The porous film 63 is exposed on a surface of the substrate. That is, the porous film 63 is exposed to an etching gas during the supply of the etching gas. After supplying the etching gas, as described in FIGS. 2 and 3 of the embodiment, to the substrate on which the respective films are formed in this manner, the state of the SiGe film 13 was observed. Further, for Evaluation Test 6-2, after supplying the etching gas as described in FIGS. 2 and 3 to a substrate having a similar film structure except that the porous film 63 was not formed, the state of the SiGe film 13 was observed.

In Evaluation Test 6-2, the SiGe film 13 was etched laterally, but in Evaluation Test 6-1, no lateral etching of the SiGe film 13 was observed. It is anticipated from these test results that when etching is performed as described with reference to FIGS. 2 and 3 for the wafer W having the film structure illustrated in FIGS. 1 and 2, the etching of the semiconductor film 16 adjacent to the porous film 14 is likely to be prevented.

According to the present disclosure in some embodiments, when etching a silicon germanium film, it is possible to prevent a film adjacent to the silicon germanium film from being etched, and to reduce residues after etching.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. An etching method of etching a silicon germanium film formed on a substrate, comprising:
supplying a first etching gas, which is a first fluorine-containing gas, to the substrate for a first duration; and
after the supplying the first etching gas, supplying a second etching gas, which is a second fluorine-containing gas different from the first etching gas, to the substrate for a second duration shorter than the first duration.

2. The etching method of claim 1, wherein in the supplying the first etching gas, the silicon germanium film is selectively etched among the silicon germanium film and a silicon film, which are exposed on a surface of the substrate; and
wherein in the supplying the second etching gas, a residue of the silicon germanium film is etched.

3. The etching method of claim 2, wherein the second etching gas is a chlorine trifluoride gas.

4. The etching method of claim 3, wherein the substrate includes a silicon-containing film and a porous film interposed between the silicon-containing film and the silicon germanium film.

5. The etching method of claim 1, wherein in the supplying the first etching gas and the supplying the second etching gas, the first etching gas and the second etching gas are supplied, respectively, to the substrate stored in a processing container; and
wherein an internal pressure of the processing container in the supplying the second etching gas is set to be lower than the internal pressure of the processing container in the supplying the first etching gas.

6. An etching apparatus for etching a silicon germanium film formed on a substrate, comprising:
a processing container configured to store the substrate;
a first gas supplier configured to supply a first etching gas, which is a first fluorine-containing gas, into the processing container for a first duration; and
a second gas supplier configured to supply a second etching gas, which is a second fluorine-containing gas different from the first etching gas, into the processing container for a second duration shorter than the first duration, after supplying the first etching gas.
